(19) United States
(12) Patent Application Publication
(10) Pub. No.: US 2022/0217870 A1
(43) Pub. Date: Jul. 7, 2022

(54) CIRCUIT BOARDS FOR ELECTRONIC DEVICES

(71) Applicant: Hewlett-Packard Development Company, L.P., Spring, TX (US)

(72) Inventors: Owen P. Columbus, Spring, TX (US); Jamil Abdul Wakil, Spring, TX (US); Monji G. Jabori, Spring, TX (US); Xiang Ma, Spring, TX (US); Rafael Ibanez, Spring, TX (US)

(73) Assignee: Hewlett-Packard Development Company, L.P., Spring, TX (US)

(21) Appl. No.: 17/608,494

(22) PCT Filed: Sep. 6, 2019
(86) PCT No.: PCT/US2019/050099

§ 371 Date: Nov. 3, 2021

(51) Int. Cl. H05K 7/20; H05K 7/10; G06F 1/20

(52) U.S. Cl. CPC H05K 7/20336; H05K 7/20409; G06F 2200/201; G06F 1/203; H05K 7/20136; H05K 7/1092

(57) ABSTRACT

Example devices include a graphics processing unit (GPU), a central processing unit (CPU), and a vapor chamber. The 0 vapor chamber includes a first side in contact with the CPU and a second side in contact with the GPU. In addition, the vapor chamber includes a fluid disposed therein that is to vaporize to transfer heat from the GPU and the CPU.

### BACKGROUND

Electronic devices may include circuit boards that carry a number of electronic components. For instance, a circuit board may include a central processing unit (CPU), a graphics processing unit (GPU), a memory, and a host of other components and devices for operating the associated electronic device.

### BRIEF DESCRIPTION OF THE DRAWINGS

Various examples will be described below referring to the following figures:

FIG. 1 is a perspective view of an electronic device according to some examples;

FIG. 2 is a schematic side view of the electronic device of FIG. 1 according to some examples;

FIG. 3 is a side, partial cross-sectional view of a circuit board of the electronic device of FIG. 1 according to some examples; and

FIG. 4 is an exploded view of the circuit board of FIG. 3 according to some examples.

### DETAILED DESCRIPTION

In the figures, certain features and components disclosed herein may be shown exaggerated in scale or in somewhat schematic form, and some details of certain elements may not be shown in the interest of clarity and conciseness. In some of the figures, in order to improve clarity and conciseness, a component or an aspect of a component may be omitted.

In the following discussion and in the claims, the terms “including” and “comprising” are used in an open-ended fashion, and thus should be interpreted to mean “including, but not limited to. . . . ” Also, the term “couple” or “couples” is intended to be broad enough to encompass both indirect and direct connections. Thus, if a first device couples to a second device, that connection may be through a direct connection or through an indirect connection via other devices, components, and connections. In addition, as used herein, the terms “axial” and “axially” generally refer to positions along or parallel to a central or longitudinal axis (e.g., central axis of a body or a port), while the terms “radial” and “radially” generally refer to positions located or spaced to the side of the central or longitudinal axis.

As used herein, including in the claims, the word “or” is used in an inclusive manner. For example, “A or B” means any of the following: “A” alone, “B” alone, or both “A” and “B.” In addition, when used herein including the claims, the word “generally” or “substantially” means within a range of plus or minus 10% of the stated value. As used herein, the term “electronic device,” refers to an device that is to carry out machine readable instructions, and may include internal components, such as, processors, power sources, memory devices, etc. For example, an electronic device may include, among other things, a personal computer, a smart phone, a tablet computer, a laptop computer, a personal data assistant, etc.

As previously described, circuit boards within electronic devices may support a plurality of electronic components (e.g., central processing units (CPUs), graphics processing units (GPUs), memories, etc.). Some of these electronic components generate heat during operations. To maintain an acceptable temperature within the housing of the electronic device, heat transfer mechanisms, structures, assemblies, etc., may be used to remove the heat generated by the electronic components. However, there is a continued push to decrease the size of electronic components. As a result, these heat generating components may be brought into closer proximity, which may prevent a heat transfer assembly from effectively removing heat generated during operations. Accordingly, examples disclosed herein include circuit boards for supporting heat generating electronic components within an electronic device that employ stacked arrangements so as to accommodate a smaller foot print within the electronic device, while still allowing for sufficient heat transfer from the heat generating components during operations. In some examples, a circuit board may include a CPU and a GPU stacked on opposing sides of a heat transfer assembly.

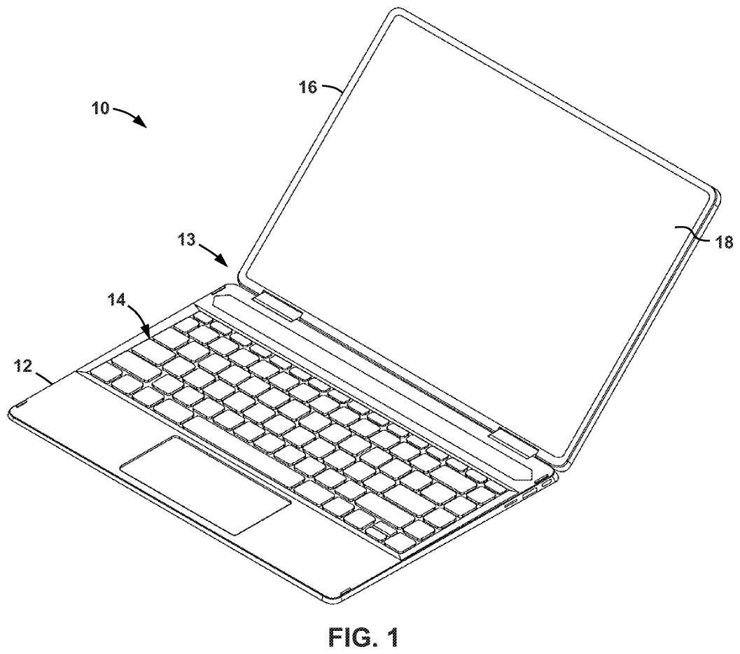

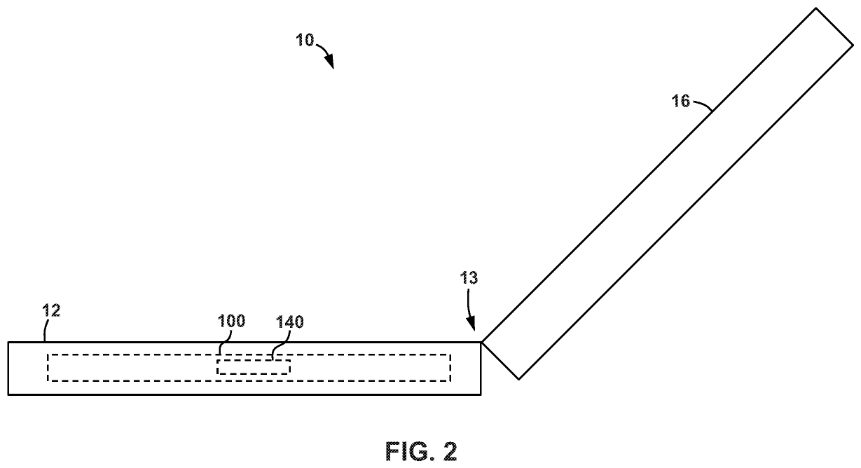

Referring now to FIGS. 1 and 2, an electronic device 10 according to some examples is shown. In this example, electronic device 10 is a laptop computer that includes a first housing member 12 rotatably coupled to a second housing member 16 at a hinge 13. The first housing member 12 includes a user input device, such as, for example, a keyboard 14. The second housing member 16 includes an electronic display 18 (or more simply “display 18”) that is to project images for viewing by a user (not shown) of the electronic device 10.

In other examples, electronic device 10 may comprise another type of electronic device (that is, other than a laptop computer as shown in FIGS. 1 and 2). For instance, in other examples, electronic device 10 may comprise any of the other electronic devices above (e.g., a tablet computer, smartphone, desktop computer, server, etc.).

Referring specifically to FIG. 2, a circuit board 100 is disposed within first housing member 12. As will be described in more detail below, circuit board 100 may support a number of heat generating components (e.g., CPU, GPU, etc.) that are used during operation of electronic device 10. In addition, the circuit board 100 includes a heat transfer assembly 140 comprising a vapor chamber that transfers heat from a plurality of the heat generating components during operations. Further details of examples of circuit board 100 are now discussed below.

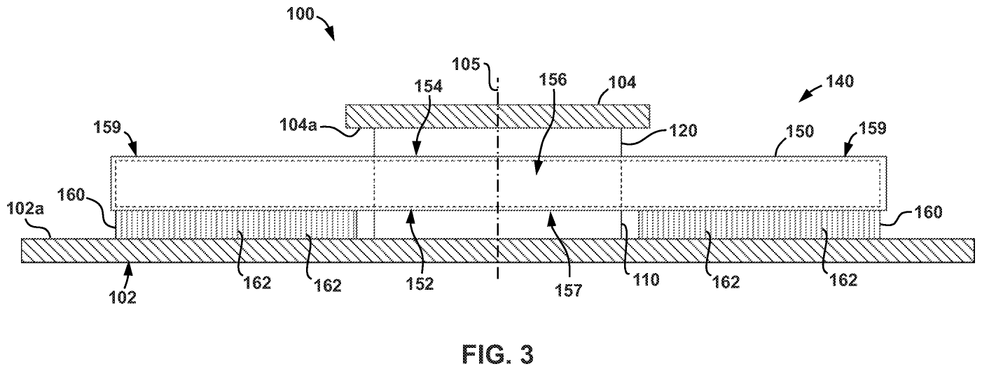

Referring now to FIG. 3, an example of circuit board 100 that may be used within electronic device 10 is shown. Generally speaking, circuit board 100 includes a first substrate 102, a second substrate 104, a CPU 110 coupled first substrate 102, a GPU 120 coupled to second substrate 104, and heat transfer assembly 140 coupled between the CPU 110 and GPU 120.

The substrates 102, 104 may comprise any suitable platform or support surface for physically supporting and (in some examples) electronically coupling electronic components (e.g., CPU 110, GPU 120) to other components (e.g., such as those that may be coupled to circuit board 100 and/or adjacent thereto). In some examples, substrates 102, 104 comprise a plurality of electrically conductive and insulating layers laminated together. For instance, in some examples, substrate 102 and/or substrate 104 may comprise alternating layers of electrically insulating materials (e.g., composite materials including fiber glass, epoxy resin, etc.) and an electrically conductive material (e.g., copper). The first substrate 102 and second substrate 104 include support surfaces 102a and 104a, respectively, that are to support electronic components (e.g., CPU 110, GPU 120, etc.) during operations.

CPU 110 may be a processor of an electronic device (e.g., electronic device 10 in FIGS. 1 and 2). The CPU 110 may execute machine readable instructions that are stored (e.g., partially, wholly, etc.) on a memory device (e.g., volatile and/or non-volatile memory devices). GPU 120 may comprise suitable circuitry or components (e.g., processors, controllers, etc.) that are to generate images that are then output to a display of a corresponding electronic device (e.g., such as display 18 of electronic device 10 in FIGS. 1 and 2). CPU 110 is secured to support surface 102a of first substrate 102, and GPU 120 is secured to support surface 104a of second substrate 104. Any suitable method or mechanism may be used to secure CPU 110 and GPU 120 to support surfaces 102a and 104a, respectively, such as, for instance, soldering, screws, pins, latches, etc.

Together, the CPU 110 and GPU 120 may operate to execute machine readable instructions and output corresponding images (e.g., still images, videos, etc.) to a display of an electronic device during operations. However, the operation of the CPU 110 and GPU 120 generate heat (e.g., due to electrical resistance therein) that may eventually cause damage to the CPU 110, GPU 120 or other components within the electronic device (e.g., electronic device 10) if not properly removed. Accordingly, the heat transfer assembly 140 may be in contact with both the CPU 110 and GPU 120 so as to draw heat away from these components during computing operations.

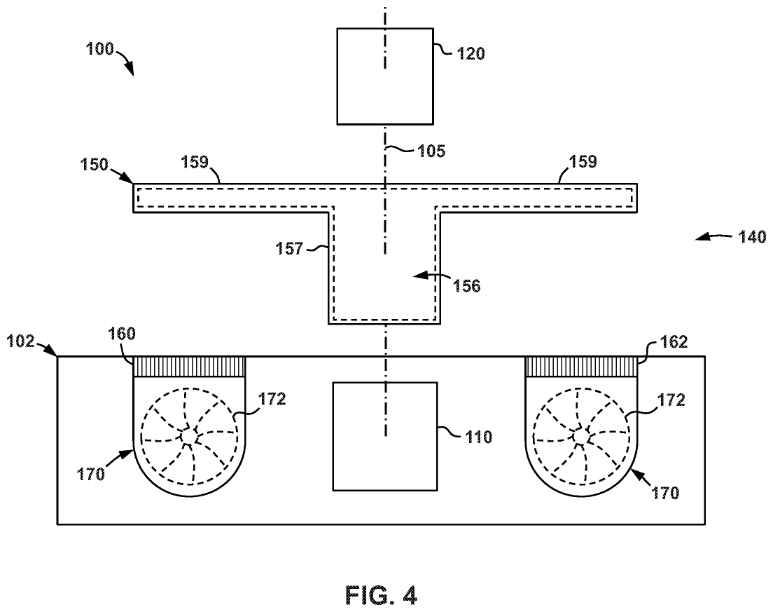

Referring now to FIGS. 3 and 4, heat transfer assembly 140 includes a vapor chamber 150, and a pair of fin banks 160. Vapor chamber 150 is a generally hollow member that defines an inner cavity 156. The inner cavity 156 may be filled (e.g., partially or wholly) with a fluid that is to change phase (e.g., from liquid to vapor) when exposed to heat (e.g., heat transferred into the cavity 156 from CPU 110 and GPU 120 during operations). In some examples, the fluid within cavity 156 comprises water. The vapor chamber 150 may be constructed from a thermally conductive material so as to efficiently conduct heat into the cavity 156 during operations. For instance, in some examples, vapor chamber 150 is constructed from copper.

As best shown in FIG. 4, vapor chamber 150 includes a central body 157, and a pair of lateral extensions 159 extending outward from central body 157. Cavity 156 may be defined within both the central body 157 and the lateral extensions 159. In some examples, the lateral extensions 159 may extend from opposing sides of the central body 157 such that vapor chamber 150 is generally T-shaped.

Vapor chamber 150 (including the central body 157 and lateral extensions 159) includes a first side 152 and a second side 154 opposite first side 152. The first side 152 is in contact with CPU 110 and the second side 154 is in contact with GPU 120. Thus, vapor chamber 150 is stacked between the CPU 110 and GPU 120 so as to transfer heat from both the CPU 110 and GPU 120 during operations. In addition, in some examples (e.g., such as the example of FIGS. 3 and 4), the CPU 110 and GPU 120 are disposed on and in contact with the opposite sides 152, 154 of vapor chamber 150 along the central body 157. Thus, when fully assembled, circuit board 100 may form a stack along a central axis 105 that includes, in order along the axis 105, the CPU 110, the vapor chamber 150, and the GPU 120. Thus, the stack of components formed by the CPU 110, vapor chamber 150, and GPU 120 is coupled to the support surfaces 102a, 104a of the substrates 102, 104, respectively. In some examples (e.g., such as the example of FIGS. 3 and 4), the axis 105 may extend normally (or perpendicularly) through the support surfaces 102a, 104a of substrates 102, 104, respectively.

Referring still to FIGS. 3 and 4, fin banks 160 include a plurality of parallel plates or fins 162. The fins 162 may comprise a thermally conductive material (e.g., a metallic material) such that fins 162 may conduct heat during operations. Fin banks 160 may be secured to support surface 102a of first substrate 102 via any suitable structure or mechanism (e.g., soldering, screws, latches, etc.). In addition, fins 162 are in contact with first side 152 of vapor chamber 150. Specifically, fins 162 are in contact with lateral extensions 159.

As shown in FIG. 4, each fin bank 160 is coupled to a corresponding fan 170 that includes an impeller 172 rotatably disposed therein. During operations, the impellers 172 of fan assemblies 170 may rotate to direct airflow across the fins 162 of fin banks 160 so as to convectively remove heat from the fins 162. Impellers 172 may be rotated with any suitable driver or mechanism (not shown) such as, for instance, electric motors. The airflow across the fins 162 may be directed from the fins 162 into the impellers 172 (e.g., such that impellers 172 operate in a so-called drawn air arrangement with respect to fin banks 160) or may be directed from the impeller 172 to the fins 162 (e.g., such that impellers 172 operate in a so-called forced air arrangement with respect to fin banks 160).

Referring still to FIGS. 3 and 4, during operations, CPU 110 and GPU 120 are mounted to the opposing sides 152, 154, respectively, of vapor chamber 150 in the manner described above. Thereafter, CPU 110 and GPU 120 may be utilized in a computing operation so that heat is generated within the CPU 110 and GPU 120 as described above. The heat generated by the CPU 110 and GPU 120 may be transferred (e.g., conducted) into to vapor chamber 150 via the contact at first side 152 and second side 154, respectively. The heat transferred to vapor chamber 150 may then be transferred (e.g., via convection and/or radiation) into the fluid disposed within cavity 156. As a result, the fluid may begin to vaporize (e.g., thereby forming water vapor for examples that utilize water within the vapor chamber 150). The vaporized fluid may then flow (e.g., due to a differential pressure driven by the vaporization process as well as a thermal gradient within cavity 156) into the lateral extensions 159 so as to transfer the heat (e.g., via convection and conduction) through the first side 152 of vapor chamber 150 at lateral extensions 159 into the fins 162 of fin banks 160. The airflow driven by impeller 172 may then carry heat away from fins 162 (e.g., into the outer environment surrounding the circuit board 110 and/or into the outer environment surrounding the associated electronic device).

Within lateral extensions 159, the vaporized fluid may cool (e.g., due to the heat transfer into the fins 162 described above) and therefore condense. Capillary forces acting between the relatively narrow lateral extensions 159 and the condensed fluid disposed therein may then drive the condensed fluid from the lateral extensions 159 back into the central body 157 to thereby restart the vaporization and heat transfer cycle described above.

Thus, the vapor chamber 150 may allow for effective heat transfer from the CPU 110 and GPU 120 within a stacked arrangement such that the overall footprint (e.g., a footprint in a plane extending radially to the axis 105) may be reduced. Thus, a size of the circuit board 100 may be reduced while still allowing sufficient heat to be transferred away from the electronic components (e.g., CPU 110, GPU 120, etc.) during operations.

It should be appreciated that other components may be mounted to the first side 152 and second side 154 of vapor chamber 150 in some examples. For instance, other components may be mounted to first substrate 102 adjacent CPU 110 and/or on the second substrate 104 adjacent GPU 120 that also contact the vapor chamber 150 so as to transfer heat thereto during operations. In some examples, these additional components may include for example, memories (e.g., random access memories), voltage regulators, inductors, etc. In addition, in some examples, more or less than two lateral extensions 159 may be included on vapor chamber 150. For instance, in some examples, a single lateral extension 159 or three lateral extensions 159 may be included on vapor chamber 150. In still other examples, no laterals extensions 159 may be included.

The examples disclosed herein have included circuit boards for supporting heat generating electronic components (e.g., CPU 110, GPU 120) in a stacked arrangement on either side of a vapor chamber (e.g., vapor chamber 150) of a heat transfer assembly (e.g., heat transfer assembly 140). Thus, through use of the examples disclosed herein, a circuit board may have a reduced footprint while still allowing for sufficient heat transfer from the heat generating components during operations.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. A device comprising:
a graphics processing unit (GPU);
a central processing unit (CPU); and
a vapor chamber comprising:
a first side in contact with the CPU;
a second side in contact with the GPU; and
a fluid disposed within the vapor chamber that is to vaporize to transfer heat from the GPU and the CPU.

2. The device of claim 1, comprising a fin bank, wherein the vapor chamber is coupled to the fin bank.

3. The device of claim 2, comprising a fan to flow air across the fin bank.

4. The device of claim 2, wherein the vapor chamber comprises a central body and a lateral extension extending from the central body, wherein the CPU and the GPU are in contact with the central body and the fin bank is in contact with the lateral extension.

5. The device of claim 1, wherein the GPU, CPU, and the vapor chamber are stacked on a support surface of a substrate of the circuit board.

6. The device of claim 1, wherein the fluid comprises water.

7. The device of claim 1, wherein the vapor chamber comprises a metallic material.

8. The device of claim 7, wherein the metallic material comprises copper.

9. A device, comprising:
a housing; and
a circuit board disposed within the housing, wherein the circuit board comprises a support surface and a stack of components coupled to the support surface, wherein the stack of components comprises:
a graphic processing unit (GPU);
a central processing unit (CPU); and
a vapor chamber,
wherein the CPU and GPU are disposed on opposite sides of the vapor chamber along an axis that extends normally to the support surface.

10. The device of claim 9, wherein the vapor chamber comprises a fluid that is to vaporize to transfer heat from the GPU and the CPU.

11. The device of claim 10, comprising a fin bank coupled to the vapor chamber.

12. The device of claim 11, comprising a fan to flow air across the fin bank.

13. A device comprising:
a substrate comprising a support surface;
a central processing unit (CPU) disposed on the support surface;
a vapor chamber disposed on the CPU; and
a graphics processing unit (GPU) disposed on the vapor chamber.

14. The device of claim 13, comprising a fin bank coupled to the vapor chamber.

15. The device of claim 14, comprising a fan to flow air across the fin bank.
